(19) United States
(12) Patent Application Publication
(10) Pub. No.: US 2024/0322022 A1
(43) Pub. Date: Sep. 26, 2024

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Yuji EBIIKE, Tokyo (JP); Kohei SAKO, Tokyo (JP)

(73) Assignee: Mitsubishi Electric Corporation, Tokyo (JP)

(21) Appl. No.: 18/414,404

(22) Filed: Jan. 16, 2024

(30) Foreign Application Priority Data
Mar. 20, 2023 (JP) 2023-043910

(51) Int. Cl. H01L 29/739; H01L 29/06; H01L 29/10; H01L 29/66

(52) U.S. Cl. CPC H01L 29/7397; H01L 29/0692; H01L 29/1095; H01L 29/66348

(57) ABSTRACT

A semiconductor device according to the present disclosure includes a substrate, a first electrode provided on a first surface of the substrate, a second electrode provided on a second surface of the substrate, an implanted electrode provided inside a trench formed on the first surface of the substrate, an upper electrode provided inside the trench and provided closer to the first surface than the implanted electrode, and a gate insulator film that electrically separates a side wall of the trench, the implanted electrode, and the upper electrode from one another, wherein the gate insulator film includes a separation portion that separates the implanted electrode and the upper electrode from each other, the implanted electrode includes a lower layer and a modifying layer provided at a position closer to the separation portion than the lower layer, and the modifying layer has a smaller crystal grain size than the lower layer.

### BACKGROUND

### Field

The present disclosure relates to a semiconductor device and a method for manufacturing the semiconductor device.

### Background

Japanese Patent No. 6844147 discloses a semiconductor device including a semiconductor substrate of a first conductivity type and an accumulation layer of the first conductivity type which is formed on a front surface side of the semiconductor substrate and of which an impurity concentration is higher than that of the semiconductor substrate. The semiconductor device further includes a trench portion formed on the front surface of the semiconductor substrate and a transistor portion and a diode portion provided on the front surface of the semiconductor substrate. The trench portion includes a first conductive portion, a second conductive portion which is formed below the first conductive portion and below a center position in a depth direction of the accumulation layer, and an insulator film that covers a side surface of the first conductive portion and a periphery of the second conductive portion. The trench portion has a split structure in which the insulator film insulates the first conductive portion and the second conductive portion from each other.

Generally, in a semiconductor device such as that described in Japanese Patent No. 6844147, a parasitic capacitance between a gate and a collector affects switching loss. The parasitic capacitance is referred to as a feedback capacitance. In Japanese Patent No. 6844147, two different electrodes are formed in a trench. With such a structure, by connecting an upper electrode on an upper side to a gate and connecting an implanted electrode on a lower side to an emitter, a semiconductor region in a vicinity of the implanted electrode no longer contributes to the feedback capacitance. As a result, the feedback capacitance can be reduced and the switching loss can be reduced.

In a semiconductor device such as that described in Japanese Patent No. 6844147, the insulator film that electrically separates the implanted electrode and the upper electrode from each other is a silicon oxide film formed by, for example, oxidizing polysilicon formed as an implanted electrode. However, such a silicon oxide film generally has large surface irregularities. Such irregularities may cause a drop in dielectric strength between the implanted electrode and the upper electrode. Accordingly, there is a possibility that a leakage current between the emitter and the gate may increase and that reliability of a gate insulator film may decline.

### SUMMARY

The present disclosure has been made in order to solve the problem described above and an object thereof is to obtain a semiconductor device and a method for manufacturing a semiconductor device capable of suppressing surface irregularities of a gate insulator film.

The features and advantages of the present disclosure may be summarized as follows.

According to the first aspect of the present disclosure, a semiconductor device includes a substrate; a first electrode provided on a first surface of the substrate; a second electrode provided on a second surface of the substrate on a side opposite to the first surface; an implanted electrode provided inside a trench formed on the first surface of the substrate; an upper electrode provided inside the trench and provided closer to the first surface than the implanted electrode; and a gate insulator film that electrically separates a side wall of the trench, the implanted electrode, and the upper electrode from one another, wherein the gate insulator film includes a separation portion that separates the implanted electrode and the upper electrode from each other, the implanted electrode includes a lower layer and a modifying layer provided at a position closer to the separation portion than the lower layer, and the modifying layer has a smaller crystal grain size than the lower layer.

According to the second aspect of the present disclosure, a semiconductor device includes a substrate; a first electrode provided on a first surface of the substrate; a second electrode provided on a second surface of the substrate on a side opposite to the first surface; an implanted electrode provided inside a trench formed on the first surface of the substrate; an upper electrode provided inside the trench and provided closer to the first surface than the implanted electrode; and a gate insulator film that electrically separates a side wall of the trench, the implanted electrode, and the upper electrode from one another, wherein the gate insulator film includes a separation portion that separates the implanted electrode and the upper electrode from each other, the implanted electrode includes a lower layer and a modifying layer provided at a position closer to the separation portion than the lower layer, and the modifying layer has a lower impurity concentration than the lower layer.

According to the third aspect of the present disclosure, a semiconductor device includes a substrate; a first electrode provided on a first surface of the substrate; a second electrode provided on a second surface of the substrate on a side opposite to the first surface; an implanted electrode provided inside a trench formed on the first surface of the substrate; an upper electrode provided inside the trench and provided closer to the first surface than the implanted electrode; and a gate insulator film that electrically separates a side wall of the trench, the implanted electrode, and the upper electrode from one another, wherein the gate insulator film includes a separation portion that separates the implanted electrode and the upper electrode from each other, and the implanted electrode includes a lower layer and an amorphous silicon layer provided at a position closer to the separation portion than the lower layer.

According to the fourth aspect of the present disclosure, a method for manufacturing a semiconductor device includes forming a trench on a first surface of a substrate including the first surface and a second surface on a side opposite to the first surface; forming an implanted electrode inside the trench; forming a modifying layer on a side of the first surface of the implanted electrode by applying surface modification processing to the implanted electrode; forming a gate insulator film by oxidizing the modifying layer or by depositing the gate insulator film on the modifying layer; and forming an upper electrode on the gate insulator film among inside of the trench, wherein the modifying layer has a smaller crystal grain size than portions other than the modifying layer among the implanted electrode.

According to the fifth aspect of the present disclosure, a method for manufacturing a semiconductor device includes forming a trench on a first surface of a substrate including the first surface and a second surface on a side opposite to the first surface; forming an implanted electrode inside the trench; forming an amorphous silicon layer on the implanted electrode among inside of the trench; forming a gate insulator film by oxidizing the amorphous silicon layer or by depositing the gate insulator film on the amorphous silicon layer; and forming an upper electrode on the gate insulator film among inside of the trench.

Other and further objects, features and advantages of the disclosure will appear more fully from the following description.

### BRIEF DESCRIPTION OF DRAWINGS

FIG. 1 is a sectional view of a semiconductor device according to a first embodiment.

FIGS. 2 to 6 are diagrams describing a method for manufacturing the semiconductor device according to the first embodiment.

FIGS. 7 to 9 are diagrams describing a method for manufacturing the semiconductor device according to the second embodiment.

FIG. 10 is a diagram describing a method for manufacturing the semiconductor device according to a modification of the second embodiment.

### DESCRIPTION OF EMBODIMENTS

A semiconductor device and a method for manufacturing the semiconductor device according to each embodiment will be described with reference to the accompanying drawings. Components identical or corresponding to each other are indicated by the same reference characters, and repeated description of them is avoided in some cases.

### First Embodiment

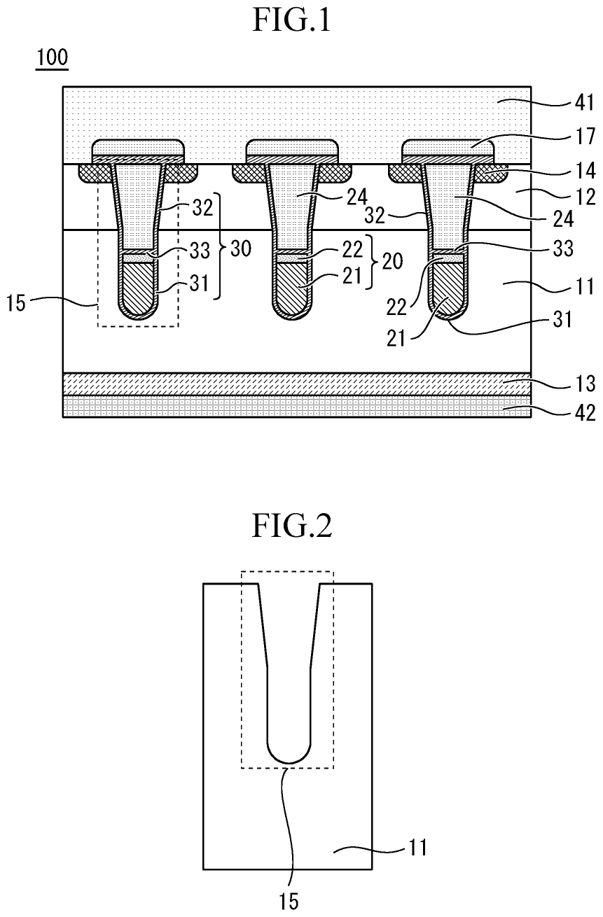

FIG. 1 is a sectional view of a semiconductor device 100 according to a first embodiment. The semiconductor device 100 is a trench-gate transistor. For example, the semiconductor device 100 is an n-channel insulated gate bipolar transistor (IGBT). The semiconductor device 100 is equipped with a substrate including a drift layer 11 of a first conductivity type. For example, the substrate is a silicon substrate. The first conductivity type is an n-type and a second conductivity type is a p-type. Conductivity types are not limited thereto and the first conductivity type may be the p-type and the second conductivity type may be the n-type. An emitter electrode 41 that is the first electrode is provided on a first surface of the substrate. A collector electrode 42 that is the second electrode is provided on a second surface of the substrate on a side opposite to the first surface.

A base layer 12 of the second conductivity type is provided on a first surface side of the drift layer 11. A collector layer 13 of the second conductivity type is provided on a second surface side of the drift layer 11. An emitter layer 14 of the first conductivity type is provided on a first surface side of the base layer 12. The emitter layer 14 is formed in a plurality of portions of a surface layer of the base layer 12. A trench 15 is formed on the first surface of the substrate. The trench 15 penetrates the emitter layer 14 and the base layer 12 from the first surface of the substrate and reaches the drift layer 11.

An implanted electrode 20 and an upper electrode 24 are provided inside the trench 15. The upper electrode 24 is provided closer to the first surface than the implanted electrode 20. A gate insulator film 30 electrically separates a side wall of the trench 15, the implanted electrode 20, and the upper electrode 24 from one another. In other words, the gate insulator film 30 includes a first portion 31 formed between the implanted electrode 20 and the side wall of the trench 15, a second portion 32 formed between the upper electrode 24 and the side wall of the trench 15, and a separation portion 33 formed between the implanted electrode 20 and the upper electrode 24. The separation portion 33 separates the implanted electrode 20 and the upper electrode 24 from each other. The gate insulator film 30 is, for example, a silicon oxide film.

An interlayer insulator film 17 for separating a gate electrode and the emitter electrode 41 from each other is provided on the upper electrode 24. The emitter electrode 41 is in contact with the base layer 12 and the emitter layer 14. Although not illustrated, the implanted electrode is connected to the emitter electrode 41 in an outer periphery of the semiconductor device 100 or the like. In addition, although not illustrated, the upper electrode 24 is connected to the gate electrode in the outer periphery of the semiconductor device 100 or the like.

The implanted electrode 20 includes a lower layer 21 and a modifying layer 22 provided at a position closer to the separation portion 33 than the lower layer 21. Both the lower layer 21 and the modifying layer 22 contain polysilicon as a main material. The modifying layer 22 has a smaller crystal grain size than the lower layer 21.

Next, a method for manufacturing the semiconductor device 100 will be described. FIGS. 2 to 6 are diagrams describing a method for manufacturing the semiconductor device 100 according to the first embodiment. First, as shown in FIG. 2, the trench 15 is formed on the first surface of the substrate including the drift layer 11. The trench 15 can be formed using a known lithography technique and a known etching technique. A depth and a width of the trench 15 are designed so that a desired breakdown voltage and desired characteristics can be secured.

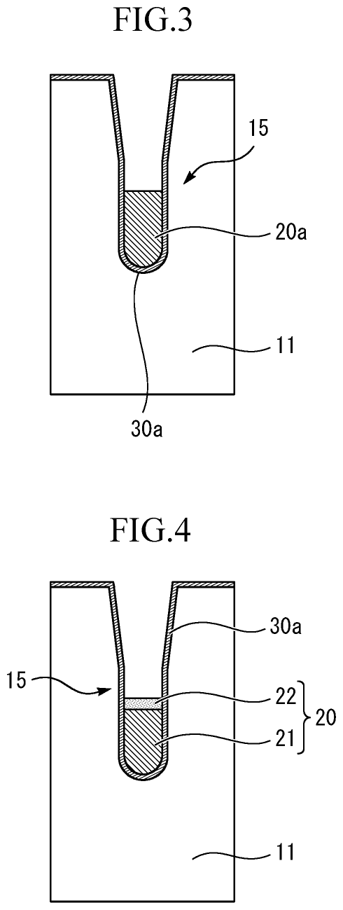

Next, as shown in FIG. 3, a gate insulator film 30a is formed on the side wall of the trench and the first surface of the substrate. For example, the gate insulator film 30a can be formed by a thermal oxidation method, a deposition method, or a combination thereof. Next, an implanted electrode 20a is formed inside the trench 15. For example, the implanted electrode 20a can be formed by depositing polysilicon by a chemical vapor deposition method. Furthermore, an upper surface of the deposited polysilicon is set to a desired depth by etch-back.

Next, as shown in FIG. 4, the implanted electrode 20a is subjected to surface modification processing. Accordingly, the modifying layer 22 is formed on the first surface side of the implanted electrode 20a. In other words, the implanted electrode 20 including the lower layer 21 and the modifying layer 22 is formed. As described above, the modifying layer 22 has a smaller crystal grain size than portions of the implanted electrode 20 other than the modifying layer 22.

For example, the modifying layer 22 is formed by ion implantation of Si into polysilicon that is a material of the implanted electrode 20a. According to such a formation method, an impurity concentration of the modifying layer 22 becomes lower than that of the lower layer 21. In this case, the modifying layer 22 can be described a layer with a lower impurity concentration than the lower layer 21.

For example, the modifying layer 22 may be formed by ion implantation of As, P, Ge, or the like into polysilicon that is a material of the implanted electrode 20a. According to such a formation method, the impurity concentration of the modifying layer 22 becomes higher than that of the lower layer 21. In this case, the modifying layer 22 can be described a layer with a higher impurity concentration than the lower layer 21.

The modifying layer 22 may formed by discharge plasma or laser irradiation. Alternatively, the modifying layer 22 may be formed by a combination of any of ion implantation, discharge plasma, and laser irradiation. In this manner, the surface modification processing includes at least one of ion implantation, plasma processing, and laser irradiation.

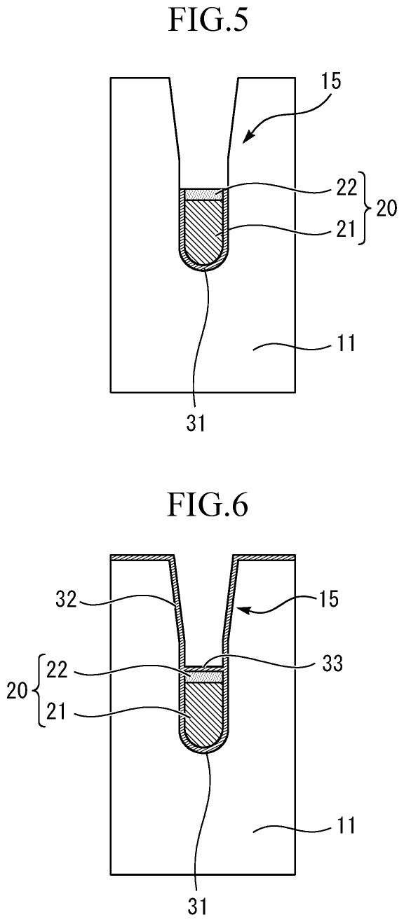

Next, as shown in FIG. 5, a portion of the gate insulator film 30a above the implanted electrode 20 is removed. Such selective etching of the gate insulator film 30a can be realized by, for example, a wet etching technique. Accordingly, the first portion 31 of the gate insulator film 30 is formed.

Next, as shown in FIG. 6, the second portion 32 and the separation portion 33 of the gate insulator film 30 are simultaneously formed on the implanted electrode 20. For example, the second portion 32 and the separation portion 33 can be formed by a thermal oxidation method, a deposition method, or a combination thereof. In other words, the separation portion 33 of the gate insulator film 30 is formed by oxidizing the modifying layer 22 or by depositing a material of the gate insulator film 30 on the modifying layer 22.

Note that the step of selectively removing the gate insulator film 30a shown in FIG. 5 may be omitted. In this case, oxidation or deposition is to be further performed on the gate insulator film 30a shown in FIG. 4. Therefore, the gate insulator film 30a is to be included in the second portion 32 and the separation portion 33.

Next, the upper electrode 24 is formed on the separation portion 33 of the gate insulator film 30 among the inside of the trench 15. Through subsequent steps, the semiconductor device 100 shown in FIG. 1 can be manufactured by a known film formation technique, a known etching technique, and a known processing technique.

Next, an advantageous effect of the present embodiment will be described. For the purpose of energy saving in power electronics equipment such as inverters, a loss of a semiconductor switching device is preferably reduced. Generally, a loss is determined by conduction loss or switching loss of the semiconductor switching device. The semiconductor device 100 according to the present embodiment includes the implanted electrode 20 and the upper electrode 24 being two electrodes in a same trench, the upper electrode 24 is connected to the gate electrode, and the implanted electrode 20 is connected to the emitter electrode. Accordingly, since the implanted electrode 20 assumes an emitter potential, feedback capacitance can be suppressed. As a result, switching loss can be reduced.

Furthermore, according to the present embodiment, an atomic arrangement of crystals is disturbed on a surface layer of the implanted electrode 20 due to surface modification processing. Accordingly, the modifying layer 22 with a small crystal grain size is formed. Forming the separation portion 33 of the gate insulator film 30 by oxidizing the modifying layer 22 with a smaller crystal grain size than the lower layer 21 enables irregularities of the surface of the separation portion 33 to be suppressed.

In addition, when the separation portion 33 is formed by a deposition method, a surface shape of the separation portion 33 inherits a shape of irregularities of the surface of the implanted electrode 20. Therefore, by depositing the material of the gate insulator film 30 on the modifying layer 22 of which a crystal grain size is small and of which surface irregularities are also small, irregularities of the surface of the separation portion 33 can be suppressed.

From the above, according to the present embodiment, flatness of the separation portion 33 can be improved and a decline in dielectric strength of the separation portion 33 can be suppressed. Accordingly, insulation properties between the emitter and the gate can be improved and reliability can be improved.

The structure and the method for manufacturing the semiconductor device 100 according to the present embodiment are examples and may be modified insofar as drawbacks are avoided. As a modification of the present embodiment, the surface modification processing may be performed on an entire surface of a wafer or may be selectively performed only on the implanted electrode 20a using a known photolithographic technique or the like. In particular, when applying the surface modification processing to the entire surface of a wafer, damaged portions other than the first portion 31 among the gate insulator film 30a can be removed by a step of selectively removing the gate insulator film 30a shown in FIG. 5.

In addition, when an atomic arrangement becomes random, polysilicon becomes amorphous silicon. In the surface modification processing, surface modification processing may be performed until polysilicon becomes amorphous silicon. In other words, the modifying layer 22 may be an amorphous silicon layer. The surface modification processing is not limited thereto and the modifying layer 22 may be kept in a microcrystalline state that is intermediate between polysilicon and amorphous silicon. Making the modifying layer 22 from amorphous silicon conceivably produces a greater effect of suppressing irregularities of the separation portion 33 than when the modifying layer 22 is microcrystalline.

Furthermore, when forming the separation portion 33 of the gate insulator film 30 by oxidizing the modifying layer 22, the modifying layer 22 may be or may not be retained as a result of the oxidation. When the modifying layer 22 is not retained, the modifying layer 22 is not present in the completed semiconductor device 100 and the separation portion 33 is provided in contact with the lower layer 21.

After forming the modifying layer 22 by the surface modification processing shown in FIG. 4, a surface of the modifying layer 22 may be further planarized before forming the separation portion 33 of the gate insulator film 30. The planarization processing is implemented by, for example, removing a surface layer of the modifying layer 22 by etching. By adding planarization processing after the surface modification, the separation portion 33 of the gate insulator film 30 to be formed later can be made even flatter.

The present embodiment has been described using an IGBT as an example. However, the present embodiment is not limited thereto and the semiconductor device 100 may be an RC (reverse-conducting)-IGBT or a metal oxide semiconductor field effect transistor (MOSFET).

In addition, the substrate may be made with a wide band-gap semiconductor. The wide band-gap semiconductor is silicon carbide, a gallium nitride-based material, or a diamond. According to the present embodiment, even when the semiconductor device 100 is made with a wide band-gap semiconductor and a high current is to flow, reliability of the gate insulator film can be improved.

These modifications can be appropriately applied to semiconductor devices and methods for manufacturing the semiconductor devices according to embodiments below. Meanwhile, for the semiconductor devices and the methods for manufacturing the semiconductor devices according to the embodiments below, dissimilarities with the first embodiment will mainly be explained as they have many similarities with the first embodiment.

### Second Embodiment

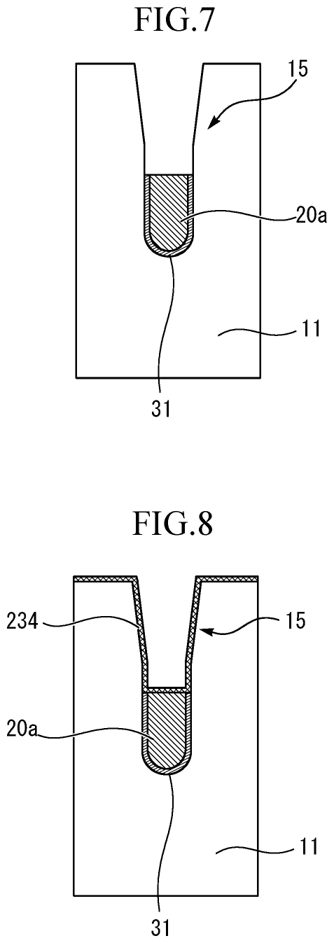

The present embodiment differs from the first embodiment in that an amorphous silicon layer is formed on an implanted electrode instead of applying surface modification processing to the implanted electrode. Otherwise, a configuration of the second embodiment is similar to the configuration of the first embodiment. FIGS. 7 to 9 are diagrams describing a method for manufacturing the semiconductor device 100 according to the second embodiment. Steps up to forming the trench 15 on the first surface of the substrate and forming the implanted electrode 20a inside the trench 15 are similar to the steps according to the first embodiment. Next, as shown in FIG. 7, a portion of the gate insulator film 30a above the implanted electrode 20a is removed to form the first portion 31. Selective etching of the gate insulator film 30a can be realized by, for example, a wet etching technique.

Next, as shown in FIG. 8, an amorphous silicon layer 234 is formed on the implanted electrode 20a and in a region where the gate insulator film 30a has been selectively removed among the inside of the trench 15. In other words, the amorphous silicon layer 234 is formed on an upper surface of the implanted electrode 20a, on a side wall of the trench 15 above the implanted electrode 20a, and on the first surface of the substrate. For example, the amorphous silicon layer 234 is formed by a chemical vapor deposition method or a plasma CVD (chemical vapor deposition) method.

Next, as shown in FIG. 9, the amorphous silicon layer 234 is oxidized to form a second portion 232 and a separation portion 233 of the gate insulator film.

Even in the present embodiment, forming the separation portion 233 of the gate insulator film by oxidizing the amorphous silicon layer 234 with a smaller crystal grain size than polysilicon enables irregularities of the surface of the separation portion 233 to be suppressed.

Alternatively, the second portion 232 and the separation portion 233 of the gate insulator film may be formed by depositing a material of the gate insulator film on the amorphous silicon layer 234. Even in this case, irregularities of the surface of the separation portion 233 can be suppressed in a similar manner to the first embodiment.

When forming the separation portion 233 of the gate insulator film by oxidizing the amorphous silicon layer 234, the amorphous silicon layer 234 on the implanted electrode 20a may be or may not be retained as a result of the oxidation. When the amorphous silicon layer 234 is not retained, a structure such as that shown in FIG. 9 is obtained. When the amorphous silicon layer 234 is retained, the amorphous silicon layer 234 is to be provided between the implanted electrode 20a and the separation portion 233 shown in FIG. 9.

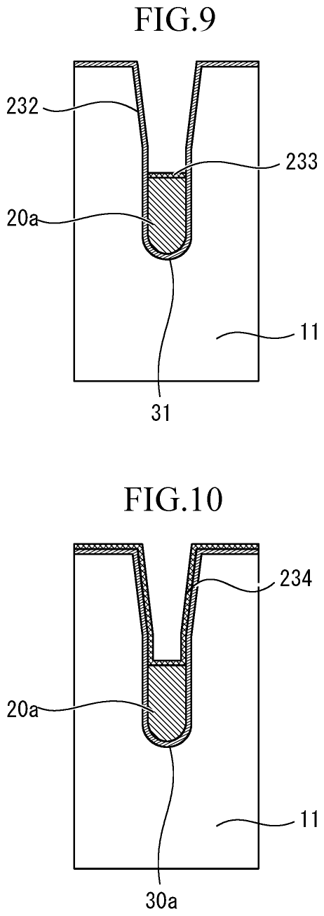

FIG. 10 is a diagram describing a method for manufacturing the semiconductor device 100 according to a modification of the second embodiment. FIG. 10 shows a state where the amorphous silicon layer 234 has been formed. In the modification, the amorphous silicon layer 234 is formed on the gate insulator film 30a. In other words, the step of selectively removing the gate insulator film 30a shown in FIG. 7 is omitted. In this case, the second portion and a portion on the first surface of the substrate of the gate insulator film become a two-layer structure of a silicon oxide film made from the amorphous silicon layer 234 and the gate insulator film 30a.

Meanwhile, technical features explained in each embodiment may be appropriately combined to use.

Hereinafter, various aspects of the present disclosure will be collectively described as appendixes.

### Appendix 1

A semiconductor device, comprising:
a substrate;
a first electrode provided on a first surface of the substrate;
a second electrode provided on a second surface of the substrate on a side opposite to the first surface;
an implanted electrode provided inside a trench formed on the first surface of the substrate;
an upper electrode provided inside the trench and provided closer to the first surface than the implanted electrode; and
a gate insulator film that electrically separates a side wall of the trench, the implanted electrode, and the upper electrode from one another, wherein
the gate insulator film includes a separation portion that separates the implanted electrode and the upper electrode from each other,
the implanted electrode includes a lower layer and a modifying layer provided at a position closer to the separation portion than the lower layer, and
the modifying layer has a smaller crystal grain size than the lower layer.

### Appendix 2

The semiconductor device according to appendix 1, wherein the modifying layer has a lower impurity concentration than the lower layer.

### Appendix 3

The semiconductor device according to appendix 1, wherein the modifying layer has a higher impurity concentration than the lower layer.

### Appendix 4

The semiconductor device according to any one of appendixes 1 to 3, wherein the modifying layer is amorphous silicon.

### Appendix 5

The semiconductor device according to any one of appendixes 1 to 4, wherein
the substrate includes:
a drift layer of a first conductivity type;
a base layer of a second conductivity type provided on a side of the first surface of the drift layer;
a collector layer of the second conductivity type provided on a side of the second surface of the drift layer; and
an emitter layer of the first conductivity type provided on a side of the first surface of the base layer, wherein
the trench penetrates the base layer and the emitter layer from the first surface of the substrate and reaches the drift layer.

### Appendix 6

The semiconductor device according to any one of appendixes 1 to 5, wherein the substrate is made with a wide band gap semiconductor.

### Appendix 7

The semiconductor device according to appendix 6, wherein the wide band gap semiconductor is silicon carbide, gallium-nitride-based material or diamond.

### (Appendix 8)

A semiconductor device, comprising:
a substrate;
a first electrode provided on a first surface of the substrate;
a second electrode provided on a second surface of the substrate on a side opposite to the first surface;
an implanted electrode provided inside a trench formed on the first surface of the substrate;
an upper electrode provided inside the trench and provided closer to the first surface than the implanted electrode; and
a gate insulator film that electrically separates a side wall of the trench, the implanted electrode, and the upper electrode from one another, wherein
the gate insulator film includes a separation portion that separates the implanted electrode and the upper electrode from each other,
the implanted electrode includes a lower layer and a modifying layer provided at a position closer to the separation portion than the lower layer, and
the modifying layer has a lower impurity concentration than the lower layer.

### (Appendix 9)

A semiconductor device, comprising:
a substrate;
a first electrode provided on a first surface of the substrate;
a second electrode provided on a second surface of the substrate on a side opposite to the first surface;
an implanted electrode provided inside a trench formed on the first surface of the substrate;
an upper electrode provided inside the trench and provided closer to the first surface than the implanted electrode; and
a gate insulator film that electrically separates a side wall of the trench, the implanted electrode, and the upper electrode from one another, wherein
the gate insulator film includes a separation portion that separates the implanted electrode and the upper electrode from each other, and
the implanted electrode includes a lower layer and an amorphous silicon layer provided at a position closer to the separation portion than the lower layer.

### Appendix 10

The semiconductor device according to appendix 8 or 9, wherein
the substrate includes:
a drift layer of a first conductivity type;
a base layer of a second conductivity type provided on a side of the first surface of the drift layer;
a collector layer of the second conductivity type provided on a side of the second surface of the drift layer; and
an emitter layer of the first conductivity type provided on a side of the first surface of the base layer, wherein
the trench penetrates the base layer and the emitter layer from the first surface of the substrate and reaches the drift layer.

### Appendix 11

The semiconductor device according to any one of appendixes 8 to 10, wherein the substrate is made with a wide band gap semiconductor.

### Appendix 12

The semiconductor device according to appendix 11, wherein the wide band gap semiconductor is silicon carbide, gallium-nitride-based material or diamond.

### (Appendix 13)

A method for manufacturing a semiconductor device, comprising:
forming a trench on a first surface of a substrate including the first surface and a second surface on a side opposite to the first surface;
forming an implanted electrode inside the trench;
forming a modifying layer on a side of the first surface of the implanted electrode by applying surface modification processing to the implanted electrode;
forming a gate insulator film by oxidizing the modifying layer or by depositing the gate insulator film on the modifying layer; and
forming an upper electrode on the gate insulator film among inside of the trench, wherein
the modifying layer has a smaller crystal grain size than portions other than the modifying layer among the implanted electrode.

### Appendix 14

The method for manufacturing a semiconductor device according to appendix 13, wherein the surface modification processing includes at least one of ion implantation, plasma processing, and laser irradiation.

### Appendix 15

The method for manufacturing a semiconductor device according to appendix 13 or 14, wherein the modifying layer is amorphous silicon.

### Appendix 16

The method for manufacturing a semiconductor device according to any one of appendixes 13 to 15, comprising planarizing a surface of the modifying layer after forming the modifying layer and before forming the gate insulator film.

### (Appendix 17)

A method for manufacturing a semiconductor device, comprising:
forming a trench on a first surface of a substrate including the first surface and a second surface on a side opposite to the first surface;
forming an implanted electrode inside the trench;
forming an amorphous silicon layer on the implanted electrode among inside of the trench;
forming a gate insulator film by oxidizing the amorphous silicon layer or by depositing the gate insulator film on the amorphous silicon layer; and
forming an upper electrode on the gate insulator film among inside of the trench.

With the semiconductor devices according to the first, second, and third disclosures and the methods of manufacturing a semiconductor device according to the fourth and fifth disclosures, irregularities of a surface of a gate insulator film between an implanted electrode and an upper electrode can be suppressed by a modifying layer or an amorphous silicon layer.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2023-043910, filed on Mar. 20, 2023 including specification, claims, drawings and summary, on which the Convention priority of the present application is based, are incorporated herein by reference in its entirety.

1. A semiconductor device, comprising:
a substrate;
a first electrode provided on a first surface of the substrate;
a second electrode provided on a second surface of the substrate on a side opposite to the first surface;
an implanted electrode provided inside a trench formed on the first surface of the substrate;
an upper electrode provided inside the trench and provided closer to the first surface than the implanted electrode; and
a gate insulator film that electrically separates a side wall of the trench, the implanted electrode, and the upper electrode from one another, wherein
the gate insulator film includes a separation portion that separates the implanted electrode and the upper electrode from each other,
the implanted electrode includes a lower layer and a modifying layer provided at a position closer to the separation portion than the lower layer, and
the modifying layer has a smaller crystal grain size than the lower layer.

2. The semiconductor device according to claim 1, wherein the modifying layer has a lower impurity concentration than the lower layer.

3. The semiconductor device according to claim 1, wherein the modifying layer has a higher impurity concentration than the lower layer.

4. The semiconductor device according to claim 1, wherein the modifying layer is amorphous silicon.

5. The semiconductor device according to claim 1, wherein
the substrate includes:
a drift layer of a first conductivity type;
a base layer of a second conductivity type provided on a side of the first surface of the drift layer;
a collector layer of the second conductivity type provided on a side of the second surface of the drift layer; and
an emitter layer of the first conductivity type provided on a side of the first surface of the base layer, wherein
the trench penetrates the base layer and the emitter layer from the first surface of the substrate and reaches the drift layer.

6. The semiconductor device according to claim 1, wherein the substrate is made with a wide band gap semiconductor.

7. The semiconductor device according to claim 6, wherein the wide band gap semiconductor is silicon carbide, gallium-nitride-based material or diamond.

8. A semiconductor device, comprising:
a substrate;
a first electrode provided on a first surface of the substrate;
a second electrode provided on a second surface of the substrate on a side opposite to the first surface;
an implanted electrode provided inside a trench formed on the first surface of the substrate;
an upper electrode provided inside the trench and provided closer to the first surface than the implanted electrode; and
a gate insulator film that electrically separates a side wall of the trench, the implanted electrode, and the upper electrode from one another, wherein
the gate insulator film includes a separation portion that separates the implanted electrode and the upper electrode from each other,
the implanted electrode includes a lower layer and a modifying layer provided at a position closer to the separation portion than the lower layer, and
the modifying layer has a lower impurity concentration than the lower layer.

9. A semiconductor device, comprising:
a substrate;
a first electrode provided on a first surface of the substrate;
a second electrode provided on a second surface of the substrate on a side opposite to the first surface;
an implanted electrode provided inside a trench formed on the first surface of the substrate;
an upper electrode provided inside the trench and provided closer to the first surface than the implanted electrode; and
a gate insulator film that electrically separates a side wall of the trench, the implanted electrode, and the upper electrode from one another, wherein
the gate insulator film includes a separation portion that separates the implanted electrode and the upper electrode from each other, and
the implanted electrode includes a lower layer and an amorphous silicon layer provided at a position closer to the separation portion than the lower layer.

10. The semiconductor device according to claim 8, wherein
the substrate includes:
a drift layer of a first conductivity type;
a base layer of a second conductivity type provided on a side of the first surface of the drift layer;
a collector layer of the second conductivity type provided on a side of the second surface of the drift layer; and
an emitter layer of the first conductivity type provided on a side of the first surface of the base layer, wherein
the trench penetrates the base layer and the emitter layer from the first surface of the substrate and reaches the drift layer.

11. The semiconductor device according to claim 8, wherein the substrate is made with a wide band gap semiconductor.

12. The semiconductor device according to claim 11, wherein the wide band gap semiconductor is silicon carbide, gallium-nitride-based material or diamond.

13. A method for manufacturing a semiconductor device, comprising:
forming a trench on a first surface of a substrate including the first surface and a second surface on a side opposite to the first surface;
forming an implanted electrode inside the trench;
forming a modifying layer on a side of the first surface of the implanted electrode by applying surface modification processing to the implanted electrode;
forming a gate insulator film by oxidizing the modifying layer or by depositing the gate insulator film on the modifying layer; and
forming an upper electrode on the gate insulator film among inside of the trench, wherein
the modifying layer has a smaller crystal grain size than portions other than the modifying layer among the implanted electrode.

14. The method for manufacturing a semiconductor device according to claim 13, wherein the surface modification processing includes at least one of ion implantation, plasma processing, and laser irradiation.

15. The method for manufacturing a semiconductor device according to claim 13, wherein the modifying layer is amorphous silicon.

16. The method for manufacturing a semiconductor device according to claim 13, comprising planarizing a surface of the modifying layer after forming the modifying layer and before forming the gate insulator film.

17. A method for manufacturing a semiconductor device, comprising:
forming a trench on a first surface of a substrate including the first surface and a second surface on a side opposite to the first surface;
forming an implanted electrode inside the trench;
forming an amorphous silicon layer on the implanted electrode among inside of the trench;
forming a gate insulator film by oxidizing the amorphous silicon layer or by depositing the gate insulator film on the amorphous silicon layer; and
forming an upper electrode on the gate insulator film among inside of the trench.

18. The semiconductor device according to claim 9, wherein
the substrate includes:
a drift layer of a first conductivity type;
a base layer of a second conductivity type provided on a side of the first surface of the drift layer;
a collector layer of the second conductivity type provided on a side of the second surface of the drift layer; and
an emitter layer of the first conductivity type provided on a side of the first surface of the base layer, wherein
the trench penetrates the base layer and the emitter layer from the first surface of the substrate and reaches the drift layer.

19. The semiconductor device according to claim 9, wherein the substrate is made with a wide band gap semiconductor.

20. The semiconductor device according to claim 19, wherein the wide band gap semiconductor is silicon carbide, gallium-nitride-based material or diamond.
